(19) United States
(12) Patent Application Publication
(10) Pub. No.: US 2015/0021177 A1
(43) Pub. Date: Jan. 22, 2015

(54) SPUTTERING DEVICE

(71) Applicant: NITTO DENKO CORPORATION, Osaka (JP)

(72) Inventors: Tomotake Nashiki, Osaka (JP); Akira Hamada, Osaka (JP)

(73) Assignee: NITTO DENKO CORPORATION, Osaka (JP)

(21) Appl. No.: 14/331,406

(22) Filed: Jul. 15, 2014

(30) Foreign Application Priority Data
Jul. 19, 2013 (JP) 2013-150739

(51) Int. Cl. H01J 37/32

(52) U.S. Cl. CPC H01J 37/32733; H01J 2237/332
USPC 204/298.28

(57) ABSTRACT

A sputtering device includes a vacuum chamber; a film depositing roll; at least one target material; a gas supply mechanism; three drive rolls (downstream conveying rolls); and three temperature control mechanisms for maintaining a temperatures of the drive rolls substantially constant in a range where the temperature is 80° C. or less and is higher than a minimum temperature in the vacuum chamber so that a long film substrate that is detached from the film depositing roll and is conveyed to the downstream conveying rolls is not deformed by rapid cooling.

### BACKGROUND OF THE INVENTION

1. Field of the Invention

The present invention relates to a sputtering device for forming a thin layer on a surface of a long film substrate conveyed along a surface of a film depositing roll.

2. Description of Related Art

A sputtering device is conventionally used, a vacuum chamber of which is provided with a material roll wound with a long film substrate; a film depositing roll to which the long film substrate conforms; a target material for forming a film depositing material on a surface of the long film substrate conveyed along a surface of the film depositing roll; a gas supply mechanism for supplying gas into a film depositing space between the film depositing roll and the target material; a downstream conveying roll for conveying the long film substrate conveyed along the surface of the film depositing roll to a downstream side of a conveyance direction; and a wind-up roll for winding the long film substrate conveyed to the downstream side of the conveyance direction from the downstream conveying roll. The above is shown in paragraphs [0012], [0023] and FIG. 1 of Japanese Unexamined Patent Application Publication No. 2003-328124 A, for example. The long film substrate sputtered by this sputtering device is used as a front panel or the like of a touch panel.

For example, the sputtering device described above conveys a long film substrate made of polyethylene terephthalate along the film depositing roll, uses indium-tin alloy as a target, and supplies reactive gas including oxygen gas as well as inert gas including argon gas into the film depositing space. The target material forms the film depositing material on the surface of the long film substrate. Thus, a thin layer of indium tin oxide (ITO) is continuously formed on the surface of the long film substrate.

Here, the film depositing roll needs to be heated to 60° C. to 70° C. by a built-in heater for depositing a film on the long film substrate. As such, when the long film substrate on which a thin layer is formed over the film depositing roll is conveyed to the downstream conveying roll on the downstream side of the conveyance direction and leaves the film depositing roll, the long film substrate in contact with the downstream conveying roll is rapidly cooled approximately to a temperature of the downstream conveying roll. For example, when the temperature of the downstream conveying roll is the same as a room temperature in the vacuum chamber, the long film substrate conveyed to the downstream conveying roll is rapidly cooled approximately to the temperature in the vacuum chamber.

This may deform the long film substrate that is conveyed to the downstream conveying roll and is cooled rapidly, and a problem may arise that the long film substrate deformed cannot be used as the front panel or the like of the touch panel or its appearance is undesirable. In particular, when the width of a long film substrate is great or when a linear expansion coefficient of a long film substrate is great, such a problem becomes prominent.

### SUMMARY OF THE INVENTION

The present invention has been made in view of the foregoing problem in the conventional sputtering device. That is, an object of the present invention is to provide a sputtering device in which a long film substrate that leaves a film depositing roll and is conveyed to a downstream conveying roll is not deformed by rapid cooling.

The summary of the present invention is described as below.

In a first preferred aspect of the present invention, a sputtering device for forming a thin layer on a surface of a long film substrate conveyed along a surface of a film depositing roll includes: a vacuum chamber; the film depositing roll disposed rotatably in the vacuum chamber; at least one target material that is disposed in the vacuum chamber and forms a film depositing material on the surface of the long film substrate conveyed along the surface of the film depositing roll; a gas supply mechanism for supplying gas into a film depositing space between the film depositing roll and the target material; a plurality of downstream conveying rolls that are disposed downstream in a conveyance direction of the long film substrate relative to the film depositing roll in the vacuum chamber and convey the long film substrate conveyed along the surface of the film depositing roll to a downstream side of the conveyance direction; and a temperature control mechanism for maintaining a temperature of at least one of the plurality of downstream conveying rolls substantially constant in a range where the temperature is 80° C. or lower and is higher than a minimum temperature in the vacuum chamber.

The downstream conveying roll is a conveying roll that is disposed downstream in the conveyance direction of the long film substrate relative to the film depositing roll and includes a drive roll rotated by a drive unit and a freely rotatable guide roll. The minimum temperature in the vacuum chamber is a temperature of a solid such as a roll disposed in the vacuum chamber or the lowest temperature among the temperatures of gas present in the vacuum chamber.

In the sputtering device according to a second preferred aspect of the present invention, the temperature control mechanism maintains the temperatures of two or more of the plurality of downstream conveying rolls substantially constant.

In the sputtering device according to a third preferred aspect of the present invention, the two or more of the downstream conveying rolls whose temperatures are maintained substantially constant by the temperature control mechanism are maintained at a lower temperature as the downstream conveying rolls are located downstream in the conveyance direction.

In the sputtering device according to a fourth preferred aspect of the present invention, the downstream conveying roll whose temperature is maintained substantially constant by the temperature control mechanism has a hollow portion and the temperature control mechanism supplies fluid of substantially constant temperature to the hollow portion.

In the sputtering device according to a fifth preferred aspect of the present invention, the temperature control mechanism has a rotary joint or a swivel joint for directing fluid into the hollow portion of the downstream conveying roll.

In the sputtering device according to a sixth preferred aspect of the present invention, the downstream conveying roll whose temperature is maintained substantially constant by the temperature control mechanism is a drive roll rotated by a drive unit.

### ADVANTAGES OF THE INVENTION

According to the sputtering device of the present invention, the long film substrate detached from the film depositing roll is cooled by contact with a downstream conveying roll whose temperature is maintained substantially constant by a temperature control mechanism and the long film substrate is further cooled on the downstream side of the conveyance direction relative to the downstream conveying roll with which it has come into contact. Thus, the long film substrate detached from the film depositing roll is gradually cooled so that the long film substrate detached from the film depositing roll is neither cooled rapidly nor deformed.

In the case where the temperature control mechanism maintains the temperatures of two or more of the plurality of downstream conveying rolls substantially constant and the two or more of the downstream conveying rolls whose temperatures are maintained substantially constant are maintained at a lower temperature as the two or more of the downstream conveying rolls are located downstream in the conveyance direction, the long film substrate detached from the film depositing roll is gradually cooled by contact with the two or more of the downstream conveying rolls whose temperatures are maintained substantially constant. Accordingly, the long film substrate detached from the film depositing roll, which is cooled gradually until it is wound up by a wind-up roll, is neither cooled rapidly nor deformed. The temperatures of the two or more of the downstream conveying rolls maintained substantially constant, are controlled so that cooling conditions of the long film substrate detached from the film depositing roll can be adjusted so as not to deform the long film substrate.

In the case where the downstream conveying roll whose temperature is maintained substantially constant by the temperature control mechanism has a hollow portion and the temperature control mechanism supplies fluid of substantially constant temperature to the hollow portion, the temperature of the downstream conveying roll is adjusted by supplying fluid such as water to the hollow portion of a substantially cylindrical downstream conveying roll. Thus, the temperature of the downstream conveying roll can be adjusted more accurately compared to the adjustment of the temperature of the downstream conveying roll by using a heater provided in the hollow portion of the downstream conveying roll. This is because the heat transfer efficiency between the fluid and the inner wall of the hollow portion of the downstream conveying roll is higher than that between gas in the hollow portion at a low pressure and the inner wall of the hollow portion of the downstream conveying roll.

The case where the downstream conveying roll whose temperature is maintained substantially constant by the temperature control mechanism is a drive roll rotated by a drive unit and the temperature control mechanism supplies fluid of substantially constant temperature to the hollow portion of the downstream conveying roll does not preclude the downstream conveying roll whose temperature is maintained substantially constant from rotating at a constant rotation speed unlike the case where the downstream conveying roll whose temperature is maintained substantially constant is a freely rotating guide roll. That is, since the guide roll is not forced by the drive unit to rotate, it may be incapable of rotating at a constant rotation speed due to the increase in weight of water supplied in the hollow portion. In contrast, the drive roll is forced by the drive unit to rotate so that it always rotates at a constant rotational speed even when water is supplied in the hollow portion.

For a full understanding of the present invention, reference should now be made to the following detailed description of the preferred embodiments of the invention as illustrated in the accompanying drawings.

### BRIEF DESCRIPTION OF THE DRAWINGS

FIG. 1 is a schematic perspective view of a sputtering device according to the present invention;

FIG. 2 is a cross-sectional view showing a rotary joint and a drive roll of the sputtering device according to the present invention;

FIG. 3 is a piping diagram showing a temperature control mechanism of the sputtering device according to the present invention;

FIG. 4 is a piping diagram showing temperature control mechanisms in another embodiment of the sputtering device according to the present invention; and

FIG. 5 is a cross-sectional view showing a rotary joint and a drive roll in still another embodiment of the sputtering device according to the present invention.

### DESCRIPTION OF THE PREFERRED EMBODIMENTS

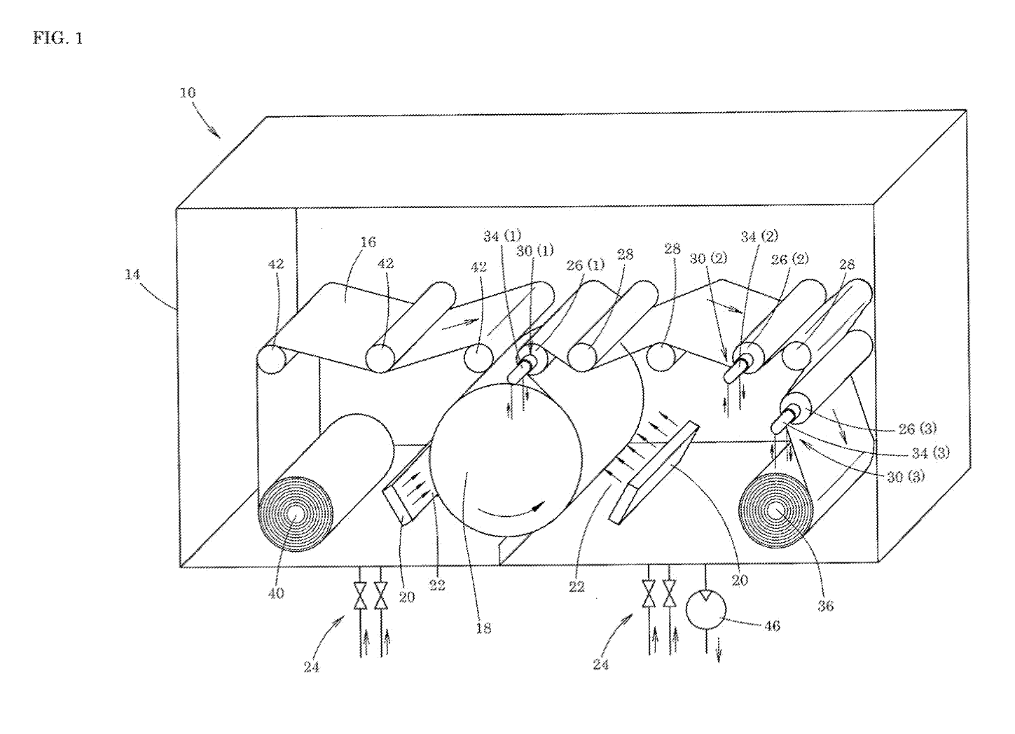

The preferred embodiments of the present invention will now be described with reference to FIG. 1 to FIG. 5 of the drawings. Identical elements in the figures are designated with the same reference numerals.

An embodiment of the present invention will now be described in detail with reference to the drawings. In FIG. 1, reference numeral 10 denotes a sputtering device according to the present invention.

The sputtering device 10, which forms a thin layer on a surface of a long film substrate 16 conveyed along a surface of a film depositing roll 18, includes a vacuum chamber 14; the film depositing roll 18 disposed rotatably in the vacuum chamber 14; a target material 20 disposed in the vacuum chamber 14 and forms a film depositing material on a surface of the long film substrate 16 conveyed along the surface of the film depositing roll 18; a gas supply mechanism 24 for supplying gas into a film depositing space 22 between the film depositing roll 18 and the target material 20; three drive rolls (downstream conveying rolls) 26(1), 26(2), 26(3) disposed downstream in the conveyance direction of the long film substrate 16 relative to the film depositing roll 18 in the vacuum chamber 14 and convey the long film substrate 16 conveyed along the surface of the film depositing roll 18 to the downstream side of the conveyance direction; and three temperature control mechanisms 30(1), 30(2), 30(3) for maintaining the temperatures of the drive rolls 26(1), 26(2), 26(3) substantially constant.

In the following, the drive roll is denoted by reference numeral “26” when the description is provided including the three drive rolls 26(1), 26(2), 26(3); the drive rolls are denoted by respective reference numerals 26(1), 26(2), 26(3) when the three drive rolls 26(1), 26(2), 26(3) are described separately. The temperature control mechanism is denoted by reference numeral “30” when the description is provided, including the three temperature control mechanisms 30(1), 30(2), 30(3); the temperature control mechanisms are denoted by respective reference numerals 30(1), 30(2), 30(3) when the three temperature control mechanisms 30(1), 30(2), 30(3) are described separately. The rotary joint is denoted by reference numeral “34” when the description is provided, including the three rotary joints 34(1), 34(2), 34(3); the rotary joints are denoted by respective reference numerals 34(1), 34(2), 34(3) when the three rotary joints 34(1), 34(2), 34(3) are described separately.

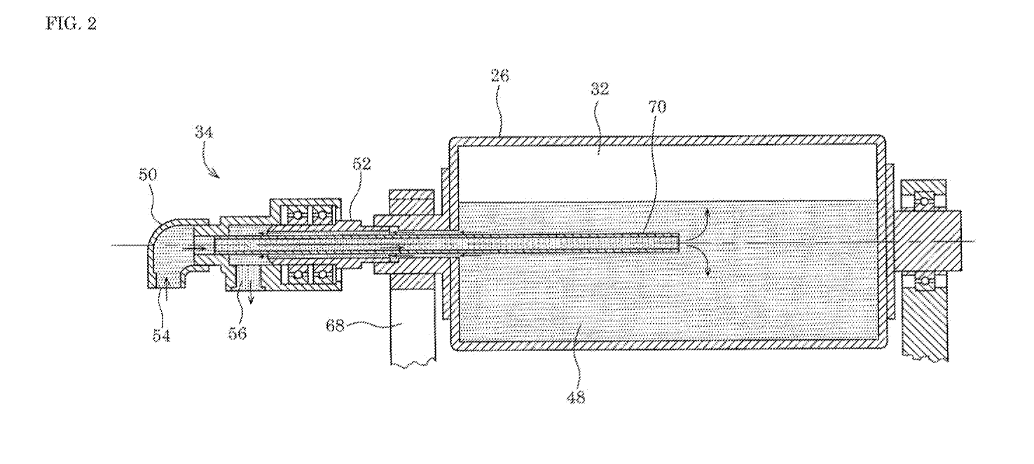

Temperature sensors (e.g., thermocouples) or thermometers, not shown, are provided at a plurality of positions in the vacuum chamber 14, which can measure the temperatures in the vacuum chamber 14. The film depositing roll 18 has a built-in heater for maintaining the surface of the film depositing roll 18 at a temperature of 60° C. to 70° C. The target material 20 includes indium-tin alloy. The gas supply mechanism 24 supplies reactive gas including oxygen gas as well as inert gas including argon gas into the film depositing space 22. The drive roll 26 has a hollow portion 32 containing water (fluid) 48. As shown in FIG. 2, the drive roll 26 is rotationally driven by a drive belt 68 shown in FIG. 2 rotated by the driving force of a motor, not shown. A cathode, such as plate cathode, dual cathode or rotary cathode, is used to maintain the target material 20 at a negative potential.

As shown in FIGS. 1 and 2, the temperature control mechanism 30 has a “dual flow and fixed inner tube” type rotary joint 34 connected to the drive roll 26.

The rotary joint 34 can deliver the water 48 from an inlet 54 through an inner tube 70 to the hollow portion 32 of the drive roll 26 and can discharge the water 48 in the hollow portion 32 from an outlet 56 while the drive roll 26 rotates. The rotary joint 34 includes a fixed member 50 secured in the vacuum chamber 14 and a rotating member 52 that is fixed to the drive roll 26 and is rotated with the drive roll 26. In FIG. 2, fixed members in the vacuum chamber 14 are indicated by descending hatching, and rotating members are indicated by rising hatching. The rotary joint 34 is known, and the structure thereof will not be further described accordingly.

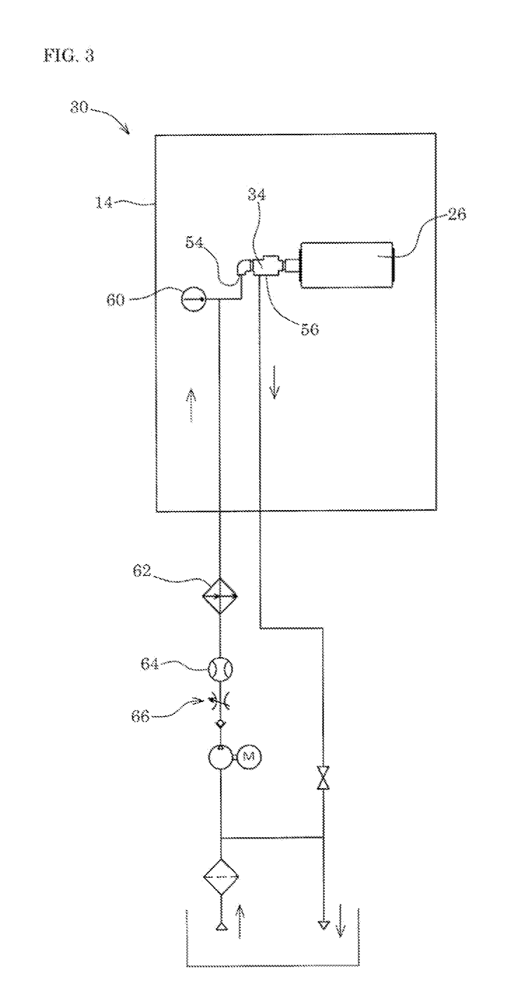

An exemplary temperature control mechanism 30 having the rotary joint 34 is shown using a piping diagram in FIG. 3. The three temperature control mechanisms 30(1), 30(2), 30(3) have the same configuration. The temperature control mechanism 30 shown in FIG. 3 is provided with a thermometer 60, a temperature controller 62, a flow meter 64, a variable throttle 66, and the like. The thermometer 60, which measures the temperature of the water 48 supplied to the hollow portion 32 of the drive roll 26, is configured such that the temperature measured can be viewed from the outside of the vacuum chamber 14. The temperature of the water supplied to the hollow portion 32 of the drive roll 26 can be adjusted manually using a temperature controller 62.

Since each of the three temperature control mechanisms 30(1), 30(2), 30(3) is provided with the temperature controller 62, the three temperature control mechanisms 30(1), 30(2), 30(3) can adjust the temperature of the water 48 at a lower level as the control mechanisms 30(1), 30(2), 30(3) are located downstream in the conveyance direction. For example, in the case where the temperature of the surface of the film depositing roll 18 is 60° C. and the minimum temperature in the vacuum chamber 14 is 20° C. around a wind-up roll 36, the temperature control mechanisms 30(1), 30(2), and 30(3), which are located from upstream to downstream in the conveyance direction, can supply the water 48 at the temperatures of 50° C., 40° C., and 30° C. to the hollow portions 32 of the drive rolls 26(1), 26(2), and 26(3), respectively.

Preferably, the following four temperature differences are substantially the same: a temperature difference between the surface of the film depositing roll 18 and the water 48 supplied from the temperature control mechanism 30(1) to the drive roll 26(1), a temperature difference between the water 48 supplied from the temperature control mechanism 30(1) to the drive roll 26(1) and the water 48 supplied from the temperature control mechanism 30(2) to the drive roll 26(2), a temperature difference between the water 48 supplied from the temperature control mechanism 30(2) to the drive roll 26(2) and the water 48 supplied from the temperature control mechanism 30(3) to the drive roll 26(3), and a temperature difference between the water 48 supplied from the temperature control mechanism 30(3) to the drive roll 26(3) and the surroundings of the wind-up roll 36. Preferably, these temperature differences are substantially the same, because the long film substrate 16 detached from the film depositing roll 18 is cooled gradually until it is conveyed to the wind-up roll 36. Additionally, in order to prevent the long film substrate 16 detached from the film depositing roll 18 from being deformed by rapid cooling, the temperature differences are preferably smaller than or equal to 20° C., in particular smaller than or equal to 10° C.

The sputtering device 10 configured as above has the following effects.

As shown in FIG. 1, the long film substrate 16 fed from a material roll 40, which is guided around guide rolls (upstream conveying rolls) 42, the film depositing roll 18, guide rolls 28, the drive rolls 26, and the wind-up roll 36, is wound into the wind-up roll 36 by the rotation of the drive rolls 26 and the wind-up roll 36.

During that time, a vacuum pump 46 maintains the vacuum chamber 14 in vacuum. The gas supply mechanism 24 supplies inert gas including argon gas and reactive gas including oxygen gas into the film depositing space 22, a voltage is applied between the film depositing roll 18 and the target material 20, and the target material 20 forms the film depositing material on the surface of the long film substrate 16. The heater built in the film depositing roll 18 maintains the surface of the film depositing roll 18 at a temperature of 60° C., for example. Thus, a thin layer of indium tin oxide is continuously formed on the surface of the long film substrate 16.

The temperature of the surface of the film depositing roll 18 is determined by the thermocouple, for example, in the vacuum chamber 14 or by the existing data. The temperature of the surface of the wind-up roll 36 is determined by the thermocouple, for example, in the vacuum chamber 14 or by the existing data. The following discussion will describe the temperature of the surface of the film depositing roll 18 as being 60° C.; the temperature of the surface of the wind-up roll 36 as being 20° C.; and the minimum temperature in the vacuum chamber 14 as being 20° C.

While a thin layer is formed on the surface of the long film substrate 16, the temperature control mechanism 30(1) supplies water at 50° C., for example, to the hollow portion 32 of the drive roll 26(1); the temperature control mechanism 30(2) supplies water at 40° C., for example, to the hollow portion 32 of the drive roll 26(2); and the temperature control mechanism 30(3) supplies water at 30° C., for example, to the hollow portion 32 of the drive roll 26(3). Therefore, the long film substrate 16, which is heated to about 60° C. by absorbing heat from the surface of the film depositing roll 18 at a temperature of 60° C., is cooled to about 50° C. by contact with the drive roll 26(1) at 50° C., is cooled to about 40° C. by contact with the drive roll 26(2) at 40° C., and is then cooled to about 30° C. by contact with the drive roll 26(3) at 30° C.

Accordingly, when the temperature of the surface of the wind-up roll 36 is 20° C., the temperature of the long film substrate 16 heated to about 60° C. gradually decreases to 20° C. in four stages from when the long film substrate 16 detached from the film depositing roll 18 until it is wound up by the wind-up roll 36. Being gradually cooled in stages, the long film substrate 16 detached from the film depositing roll 18 is not cooled rapidly. Thus, the long film substrate 16 detached from the film depositing roll 18 is not deformed by rapid cooling.

In particular, since the long film substrate 16 detached from the film depositing roll 18 first comes into contact with the drive roll 26(1) maintained at about 50° C., the long film substrate 16 immediately after being detached from the film depositing roll 18 is regulated to be cooled at a temperature of about 50° C. Thus, the long film substrate 16 immediately after being detached from the film depositing roll 18 is not deformed by rapid cooling.

Here, the downstream conveying roll to which water is supplied from the temperature control mechanism 30 may be a guide roll 28. However, since the guide roll 28 is not forced by a drive unit to rotate, it may be difficult for the guide roll 28 to rotate at a constant rotational speed because the supply of water to the hollow portion increases the weight to be supported by bearings of the guide roll 28. This may cause a problem that friction occurs between the guide roll 28 and the long film substrate 16 or the long film substrate 16 is deformed in a longitudinal direction. In contrast, the drive roll 26, which is forced by the drive belt 68 to rotate, rotates at a constant rotational speed, thereby avoiding such a problem. As such, all downstream conveying rolls to which water is supplied from the temperature control mechanism 30 are preferably driven rolls 26.

While an exemplary embodiment of the present invention has been described above, the present invention is not limited thereto.

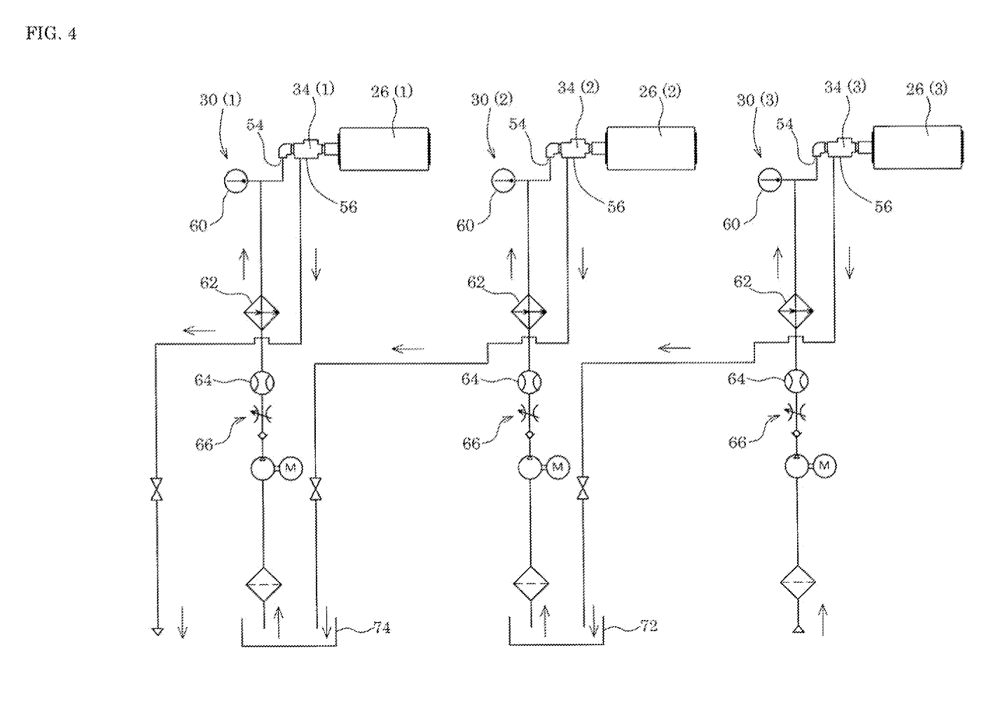

For example, piping of the temperature control mechanism 30 for use in the sputtering device 10 of the present invention is not limited to the piping described above. As shown in FIG. 4, for example, the three temperature control mechanisms 30(1), 30(2), 30(3) may be configured using piping connecting them to each other instead of being configured separately.

That is, water discharged from the outlet 56 of the rotary joint 34(3) is temporarily accumulated in a tank 72. The water accumulated in the tank 72 is supplied from the inlet 54 of the rotary joint 34(2) to the hollow portion 32 of the drive roll 26(2) and is discharged from the outlet 56 of the rotary joint 34(2). The water discharged from the outlet 56 of the rotary joint 34(2) is temporarily accumulated in a tank 74. The water accumulated in the tank 74 is supplied from the inlet 54 of the rotary joint 34(1) to the hollow portion 32 of the drive roll 26(1) and is discharged from the outlet 56 of the rotary joint 34(1).

In this case, the temperature control mechanism 30(1) supplies water 48 at 50° C. to the hollow portion 32 of the drive roll 26(1), the temperature control mechanism 30(2) supplies water 48 at 40° C. to the hollow portion 32 of the drive roll 26(2), and the temperature control mechanism 30(3) supplies water 48 at 30° C. to the hollow portion 32 of the drive roll 26(3), thereby reducing the energy to heat the water. That is, if water at a temperature of 20° C. is used for temperature control, a temperature controller 62 of the temperature control mechanism 30(3) raises the temperature of water by 10° C. from 20° C. to 30° C., the temperature controller 62 of the temperature control mechanism 30(2) raises the temperature of water by 10° C. from 30° C. to 40° C., and the temperature controller 62 of the temperature control mechanism 30(1) raises the temperature of the water by 10° C. from 40° C. to 50° C. Thus, gradually heating water at a temperature of 20° C. for temperature control can reduce the energy for heating by the temperature controller 62.

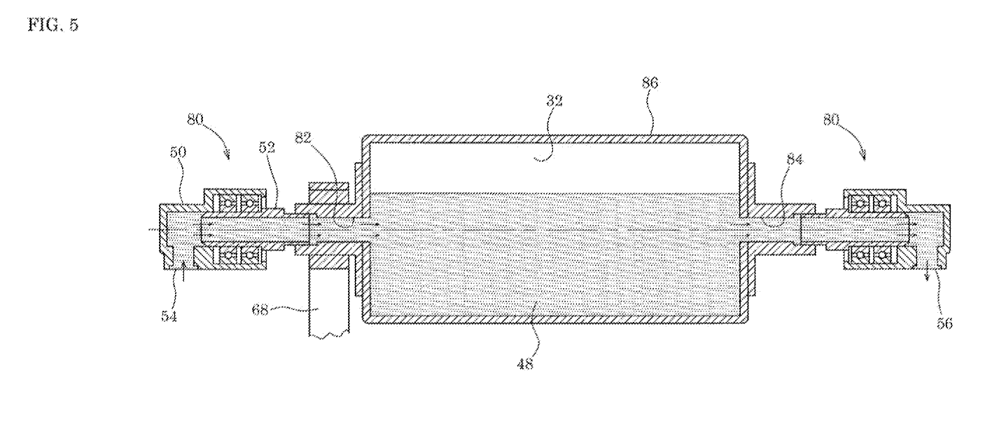

A rotary joint for use in the sputtering device 10 of the present invention is not limited to the “dual flow and fixed inner tube” type rotary joint 34 shown in FIG. 2, and it may be a “single flow and no inner tube” type rotary joint 80 shown in FIG. 5. A drive roll to be used in this case is a drive roll (downstream conveying roll) 86 that has an inlet opening 82 on an upstream side of a water flow direction and has an outlet opening 84 on a downstream side of the water flow direction. One rotary joint 80 is connected to the inlet opening 82 and the other rotary joint 80 is connected to the outlet opening 84. Even when the rotary joints 80 and the drive roll 86 are used, water is supplied from the inlet 54 to the drive roll 86 and the water is discharged from the outlet 56 while the drive roll 86 rotates, thereby the temperature of the drive roll 86 being controlled.

Although the embodiments have been described so far with reference to the drawings, the present invention is not limited to the embodiments illustrated. For example, the number of the downstream conveying rolls whose temperatures are maintained substantially constant by the temperature control mechanism is not limited to three, but rather it may be one, two, four, or more. However, the greater number of the downstream conveying rolls whose temperatures are maintained substantially constant, which enable cooling in more stages, are more preferable. The temperature control mechanism may be an electrical heater built in the downstream conveying roll. Moreover, in the present invention, the long film substrate conveyed along the surface of the film depositing roll is heated once by one downstream conveying roll and is then cooled by the other downstream conveying roll.

### INDUSTRIAL APPLICABILITY

The sputtering device according to the present invention can be widely used for sputtering onto a long film substrate having a large linear expansion coefficient, for example.

This application claims priority from Japanese Patent Application No. 2013-150739, which is incorporated herein by reference.

There has thus been shown and described a novel sputtering device which fulfills all the objects and advantages sought therefor. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

What is claimed is:

1. A sputtering device for forming a thin layer on a surface of a long film substrate conveyed along a surface of a film depositing roll, the sputtering device comprising:
a vacuum chamber;
the film depositing roll disposed rotatably in the vacuum chamber;
at least one target material that is disposed in the vacuum chamber and forms a film depositing material on the surface of the long film substrate conveyed along the surface of the film depositing roll;
a gas supply mechanism for supplying gas into a film depositing space between the film depositing roll and the at least one target material;
a plurality of downstream conveying rolls that are disposed downstream in a conveyance direction of the long film substrate relative to the film depositing roll in the vacuum chamber and convey the long film substrate conveyed along the surface of the film depositing roll to a downstream side of the conveyance direction; and
a temperature control mechanism for maintaining a temperature of at least one of the plurality of downstream conveying rolls substantially constant in a range where the temperature is 80° C. or less and is higher than a minimum temperature in the vacuum chamber.

2. The sputtering device according to claim 1, wherein the temperature control mechanism maintains the temperatures of two or more of the plurality of downstream conveying rolls substantially constant.

3. The sputtering device according to claim 2, wherein the two or more of the downstream conveying rolls whose temperatures are maintained substantially constant by the temperature control mechanism are maintained at a lower temperature as the two or more of the downstream conveying rolls are located downstream in the conveyance direction.

4. The sputtering device according to claim 1, wherein the downstream conveying roll whose temperature is maintained substantially constant by the temperature control mechanism has a hollow portion and the temperature control mechanism delivers fluid of substantially constant temperature to the hollow portion.

5. The sputtering device according to claim 4, wherein the temperature control mechanism has one of a rotary joint and a swivel joint for directing fluid into the hollow portion of the downstream conveying roll.

6. The sputtering device according to claim 1, wherein the downstream conveying roll whose temperature is maintained substantially constant by the temperature control mechanism is a drive roll rotated by a drive unit.
